(19) United States
(12) Patent Application Publication
(10) Pub. No.: US 2024/0250231 A1
(43) Pub. Date: Jul. 25, 2024

(54) SUBSTRATES FOR LED DISPLAY HEAT DISSIPATION

(71) Applicant: CORNING INCORPORATED, CORNING, NY (US)

(72) Inventors: SEAN MATTHEW GARNER, ELMIRA, NY (US); DAVID ROBERT HEINE, SEMINOLE, FL (US); DEAN MICHAEL THELEN, ADDISON, NY (US)

(21) Appl. No.: 18/562,372

(22) PCT Filed: May 18, 2022
(86) PCT No.: PCT/US2022/029856

§ 371 Date: Nov. 27, 2023

Related U.S. Application Data
(60) Provisional application No. 63/194,324, filed on May 28, 2021.

(51) Int. Cl. H01L 33/64; H01L 25/075

(52) U.S. Cl. CPC H01L 33/642; H01L 25/0753; H01L 2933/0075

(57) ABSTRACT

Apparatuses and methods are described for substrate materials and designs for controlling heat dissipation from semiconductor devices such as light-emitting diodes (LEDs). The embodiments may reduce temperature increases of semiconductor devices during operation. In some examples, a substrate structure is manufactured with a plurality of fins positioned along a first side. A plurality of heating sources, such as electronic components that generate heat, may be positioned along a second side of the substrate structure. The plurality of heat sources may be positioned to be laterally offset from the plurality of fins. In some examples, a plurality of LEDs are positioned along the first side of the substrate structure and at least partially laterally in line with the plurality of fins. In some examples, the plurality of LEDs are positioned along the first side of the substrate structure and laterally offset from the plurality of fins.

### CROSS-REFERENCE TO RELATED APPLICATION

This application claims the benefit of priority under 35 U.S.C. § 119 of U.S. Provisional Application Ser. No. 63/194,324 filed on May 28, 2021, the content of which is relied upon and incorporated herein by reference in its entirety.

### FIELD OF THE DISCLOSURE

The present disclosure relates to the production of substrates and, more particularly, to substrate materials and designs for controlling heat dissipation from semiconductor devices.

### BACKGROUND

Light-emitting diodes (LEDs), such as micro-LEDs, mini-LEDs, and organic light-emitting diodes (OLEDs), are used in a variety of applications. For example, they may be used in glass display panels such as in mobile devices, laptops, tablets, computer monitors, automotive display, smartwatch, backlights, signage, and television displays. The nearby components can include thin film transistors (TFTs), integrated circuits (ICs), conductors, color conversion elements, and other electronic elements. The LEDs and nearby components typically generate heat during operation. LEDs tend to be temperature sensitive. For example, absorbed heat may cause LEDs to be less efficient, or may even cause color shifts in emitted light. To dissipate component generated heat, some device designs include substrates that absorb and direct heat away from the LEDs. These substrates include uniform sheets of glass and printed circuit board (PCB) layered structures. The heat may be directed to a heat sink, for example. These designs, however, may have drawbacks. For example, they may not direct enough heat away from the LEDs or color conversion elements, causing the above noted inefficiencies or shifts in emitted light. In addition, current designs may not efficiently dissipate heat from LEDs or other components causing, for example, exterior device surfaces, which may be touched by consumers, to overheat. A consumer touching such an exterior device surface may burn themselves, for example. Moreover, thermal considerations can limit the display brightness level, which is a key value metric for displays, such as micro-LED displays. Thus, there are opportunities to address heat dissipation from electronic components such as within glass display panels.

### SUMMARY

The embodiments disclosed herein are directed to apparatus and methods for dissipating heat from semiconductor devices such as LEDs, color conversion elements, TFTs, ICs, conductors, and other electronic components. For example, the apparatuses and methods described herein may employ a heat dissipation mechanism that is designed to direct heat away from LEDs, such as micro-LEDs, mini-LEDs, and OLEDs, in various applications, such as glass panel displays. The embodiments may include display substrate materials and designs to direct heat away from the LEDs. For example, the embodiments may include designs and methods to channel heat from one side of a substrate (e.g., a side with electronics generating heat) to another side of the substrate where global cooling may occur. In some examples, the substrate includes 3-dimensional features, such as “fins,” to specifically channel heat away from an LED emitter's heat source and away from the temperature sensitive LED. The heat may be dissipated through laterally-isolated heat conduction paths.

Among other advantages, the embodiments may reduce heat spreading in the substrate to thermally sensitive elements. For example, the embodiments may maintain LED emitters, color conversion elements, and nearby components below a threshold temperature even though they are in close proximity to other semiconductor components that generate heat such as TFTs, conductor lines, or micro-IC components. Further, the embodiments may increase heat transfer from LEDs, color conversion elements, nearby components, and heat sources, which may allow for a lowering of LED exterior surface temperatures that a consumer may touch. Moreover, by increasing heat dissipation from LEDs, color conversion elements, and nearby components, the embodiments may allow the LEDs to maintain a stable emission spectrum and may increase the LED's lifetime reliability. By minimizing LED temperature increases, the embodiments may also allow for higher display brightness levels, as higher electrical drive currents may be employed before electronic component thermal limits, such as LED thermal limits, are reached. Additionally, the embodiments may improve heat dissipation extraction efficiencies, thereby lowering device power consumption, such as by reducing cooling fan power consumption. Those of ordinary skill in the art having the benefit of these disclosures may recognize other benefits as well.

In some embodiments, a device may comprise a substrate with a first side and a second side opposite the first side, and a plurality of heat sources positioned on the first side of the substrate at a period. The second side of the substrate comprises a plurality of fins positioned at the period, wherein the plurality of heat sources are laterally offset from the plurality of fins. In some examples, the device comprises a plurality of LEDs at least partially laterally in line with the plurality of fins. In some examples, the device comprises a plurality of LEDs laterally offset from the plurality of fins.

In some embodiments, an LED display comprises a plurality of LED devices, wherein each of the plurality of LED devices comprises a substrate with a first side and a second side opposite the first side, and a plurality of heat sources positioned on the first side of the substrate at a period. Further, the second side of the substrate comprises a plurality of fins positioned at the period, wherein the plurality of heat sources are laterally offset from the plurality of fins. In some examples, each of the plurality of LED devices comprises a plurality of LEDs at least partially laterally in line with the plurality of fins. In some examples, each of the plurality of LED devices comprises a plurality of LEDs laterally offset from the plurality of fins.

In some embodiments, a method, such as by a pick and place machine, may include forming a substrate comprising a first side and a second side opposite the first side, wherein the first side comprises a plurality of fins at a period. The method also comprises placing a plurality of heat generating elements at the period along the second side of the substrate and laterally offset from the plurality of fins.

In some examples, the method includes placing a plurality of LEDs on the second side of the substrate and at least partially laterally in line with the plurality of fins. In some examples, the method includes placing a plurality of LEDs on the second side of the substrate and laterally offset from the plurality of fins.

In some embodiments, a non-transitory computer readable medium stores instructions that, when executed by one or more processors, cause the one or more processors to perform a method that includes forming a substrate comprising a first side and a second side opposite the first side, wherein the first side comprises a plurality of fins at a period. The method also comprises placing a plurality of heat generating elements at the period along the second side of the substrate and laterally offset from the plurality of fins.

In some examples, the method includes placing a plurality of LEDs on the second side of the substrate and at least partially laterally in line with the plurality of fins. In some examples, the method includes placing a plurality of LEDs on the second side of the substrate and laterally offset from the plurality of fins.

### BRIEF DESCRIPTION OF DRAWINGS

The above summary and the below detailed description of illustrative embodiments may be read in conjunction with the appended Figures. The Figures show some of the illustrative embodiments discussed herein. As further explained below, the claims are not limited to the illustrative embodiments. For clarity and ease of reading, Figures may omit views of certain features.

FIG. 1 illustrates a device with a substrate structure to channel heat from heat sources in accordance with some examples.

FIGS. 2A, 2B, 2C, 2D, and 2E illustrate exemplary devices with substrate structures to channel heat from heat sources in accordance with some examples.

FIG. 3 illustrates a light-emitting diode device in accordance with some examples.

FIGS. 4A and 4B illustrate exemplary substrate structures in accordance with some examples.

FIGS. 5A, 5B, 5C, 5D, and 5E illustrate exemplary methods for generating devices with substrate structures in accordance with some examples.

### DETAILED DESCRIPTION

The present application discloses illustrative (i.e., example) embodiments. The disclosure is not limited to the illustrative embodiments. Therefore, many implementations of the claims will be different than the illustrative embodiments. Various modifications can be made to the claims without departing from the spirit and scope of the disclosure. The claims are intended to cover implementations with such modifications.

At times, the present application uses directional terms (e.g., front, back, top, bottom, left, right, etc.) to give the reader context when viewing the Figures. The claims, however, are not limited to the orientations shown in the Figures. Any absolute term (e.g., high, low, etc.) can be understood as disclosing a corresponding relative term (e.g., higher, lower, etc.). Moreover, although the exemplary examples discussed herein may include LED devices, the exemplary embodiments may include any type of semiconductor or emission material device.

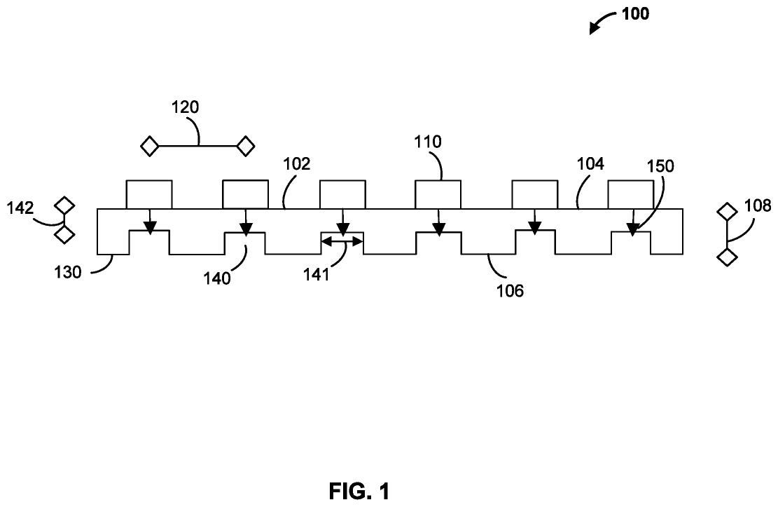

Referring to FIG. 1, device 100 includes substrate structure 102 with a first side 104 and a second side 106 opposite the first side 104. Substrate structure 102 may have a substrate thickness 108. Device 100 further includes a plurality of heat sources 110 (i.e., heat generating elements) positioned along the first side 104 of substrate structure 102 at a period 120 (e.g., pitch 120). Heat sources 110 may include electronic or semiconductor components such as, for example, drive electronics, TFTs, conductor lines, and micro-IC components. Period 120 may be an equal distance between the heat sources 110. For example, period 120 may be in the range of 25 um to 250 um, for displays with display pitches of ˜100 ppi to ˜1000 ppi, respectively. In some examples, period 120 may be the same as, or a multiple of, a display pitch.

In some examples, the heat sources 110 may be positioned proximate the first side 104. For example, an electric circuit layer, such as a metal or dielectric electric circuitry layer, may be positioned along the entirety of, or one or more select portions of, the first side 104 of substrate structure 102. The heat sources 110 may be placed atop the electric circuit layer (e.g., at the period 120). The heat sources 110 can be placed through photolithography patterning, vacuum deposition, electroplating, printing, lamination, or transfer methods, for example.

Substrate structure 102 includes a plurality of fins 130 positioned along the second side 106 of substrate 102. In this example, the plurality of fins 130 are positioned at the same period as period 120 of the plurality of heat sources 110. In an embodiment, the fins 130 are positioned in an alternating fashion with the heat sources 110. The plurality of fins 130 further define windows 140 between at least some adjacent fins 130. One or more of the windows 140 may have a width 141 which, in certain embodiments, is the same as or is approximately the same as a width of a corresponding heat source 110. In some examples one or more of the windows may have a width 141 that is 10% wider than a corresponding heat source 110. In the example illustrated in FIG. 1, a window 140 is located underneath each of the plurality of heat sources 110. For example, each window 140 is laterally aligned (e.g., vertically aligned) to a heat source 110. In some examples, each window 140 is at least partially aligned to each heat source 110. In some examples, the distance between adjacent heat sources 110 varies, with a corresponding shift in the windows 140 (e.g., a window 140 is aligned to each heat source 110).

In some examples, substrate 102 with fins 130 may be formed by removing substrate material (e.g., from a block of substrate) to carve out the fins 130. For example, substrate material may be removed from a substrate block to form the fins 130 as defined by windows 140 (e.g., windows 140 indicate the carved out substrate material). In some examples, fins 130 are attached to substrate 102 with, for example, an adhesive. The adhesive may be, for example, an acrylic, epoxy, or urethane acrylate. The fins 130 and the substrate 102 may be of a same material.

A cooling mechanism, including traditional heat sinking approaches such as air (e.g., air, oxygen, inert gas, or some other gaseous substance) flow, metal constructions, or other thermal conductor may be provided within the windows 140 to dissipate heat away from substrate 102. Arrows 150 indicate directional heat flow. In this example, the cooling mechanism within windows 140 dissipates heat generated by heating sources 110 through substrate structure 102. Thus, by providing laterally-isolated heat conduction paths, heat is channeled from the first side 104 of substrate structure 102 to the second side 106 of substrate 102.

Substrate structure 102 includes a window thickness 142 between the first side 104 of substrate structure 102 and each window 140. In some examples, substrate structure 102 is manufactured to have a window thickness 142 that is proportional to the pitch 120 by a predetermined amount. For example, substrate structure 102 may be manufactured to have a window thickness 142 that is less than a threshold percentage of the pitch 120. For example, substrate structure 102 may be manufactured to have a window thickness 142 that is less than or equal to 30% of the pitch 120 (e.g., window thickness 142<=0.3X pitch 120). As other examples, substrate structure 102 may be manufactured to have a window thickness 142 that is less than or equal to 10% of the pitch 120, less than or equal to 50% of the pitch 120, less than or equal to 70% of the pitch 120, or less than or equal to 90% of the pitch 120.

In some examples, substrate structure 102 may, additionally or alternatively, be manufactured to have a window thickness 142 that is less than a threshold percentage of the substrate thickness 108. For example, substrate structure 102 may be manufactured to have a window thickness 142 that is less than or equal to 50% of the substrate thickness 108 (e.g., window thickness 142<=0.5×substrate thickness 108).

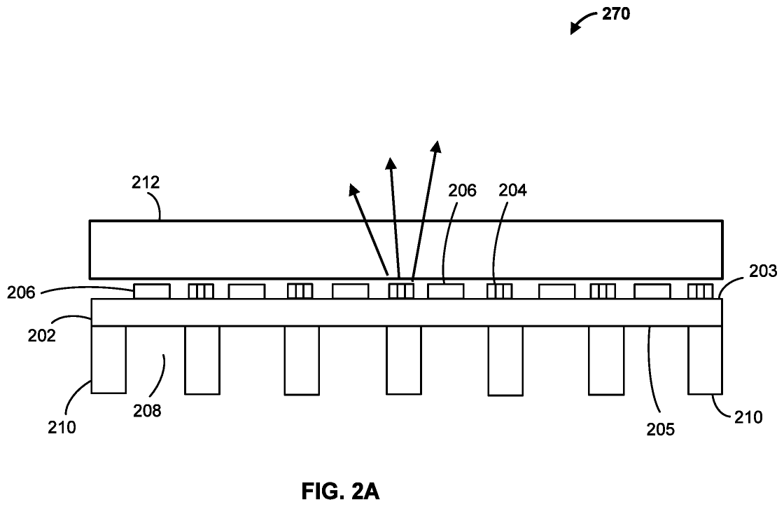

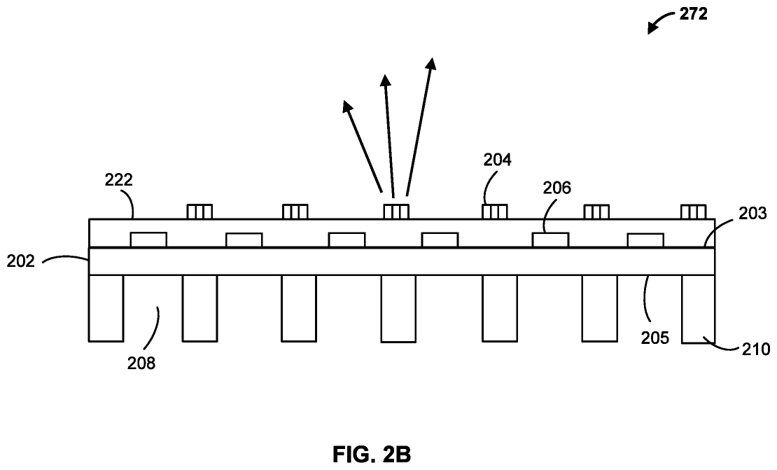

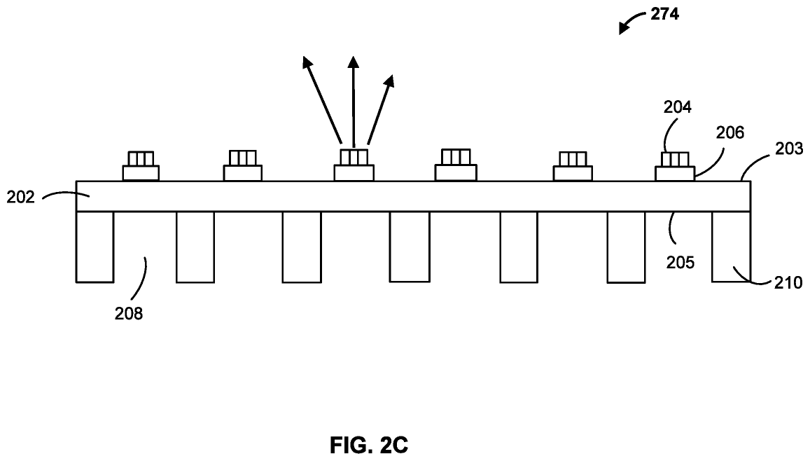

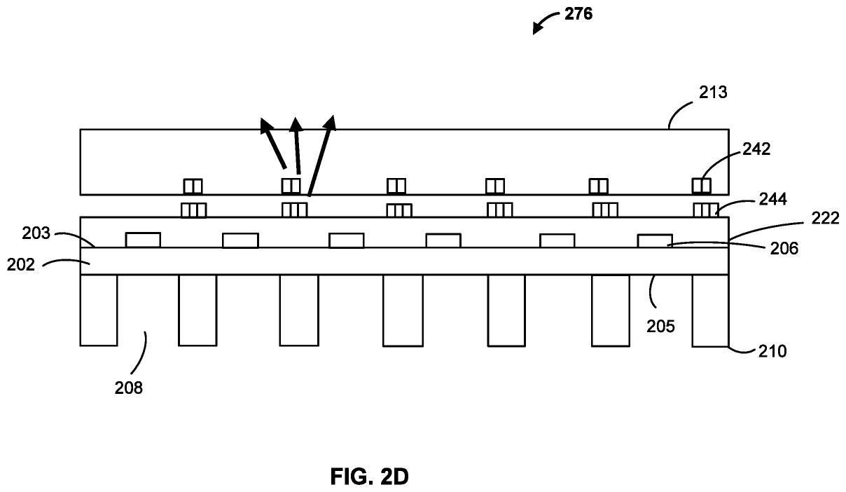

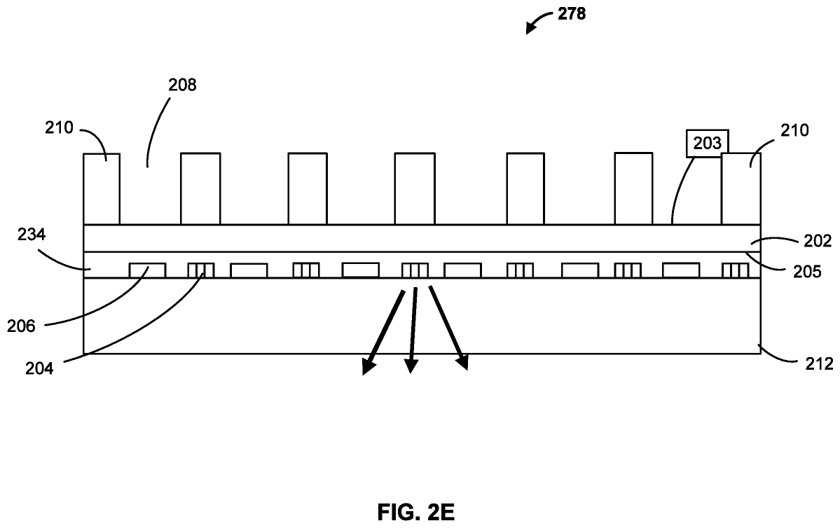

FIGS. 2A, 2B, 2C, 2D, and 2E illustrate exemplary LED device configurations. Referring to FIG. 2A, LED device 270 includes a plurality of heat sources 206 (e.g., TFT, conductor, or micro-IC components) positioned along the first side 203 of substrate structure 202. Further, substrate structure 202 includes a plurality of fins 210 positioned along the second side 205 of substrate structure 202. The plurality of fins 210 define windows 208 between at least some of adjacent fins 210. Substrate structure 202 is thicker at areas that include fins 210 compared to areas with windows 208. In some examples, the thicker substrate areas, such as fins 210, provide mechanical support (e.g., increased rigidity) and increased surface area. In some examples, substrate material is carved out from a block of substrate material to form substrate 202 with fins 210. In some examples, substrate material is removed from the block of substrate such that the fins 210 are of a same or similar shape as heat sources, such as heat sources 206.

Further, LED device 270 includes a plurality of LEDs 204 positioned along the first side of substrate structure 202 and between adjacent heat sources 206. LEDs 204 may include, for example, LEDs that emit red, green, and blue light. In this example, each LED 204 is positioned laterally aligned with a fin 210 of substrate structure 202. Heat sources 206, however, are laterally in line with windows 208. In some examples, windows 208 are manufactured to be a percentage wider than heat sources 206. For example, substrate structure 202 may be manufactured to include windows 208 that are 10% wider than heat sources 206 (e.g., window 208 width >=110% of heat source 206 width).

Because heat from heat sources 206 will tend to follow a path of least resistance, at least some of the heat emitted by each heat source 206 will be directed through substrate structure 202 to the heat source's corresponding window 208. Thus, LED device 270 directs heat from the first side 203 of substrate structure 202 to the second side 205 of the substrate structure 202. A cooling mechanism, such as a gas, metal or other thermal conductor, may be provided within windows 208 to dissipate the heat, such as by directing the heat out to the environment. LED device 270 further includes a glass sheet (e.g., cover) 212 positioned over the first side 203 of substrate structure 202 through which LEDs 204 emit light.

FIG. 2B illustrates an LED device 272 that includes a plurality of heat sources 206 (e.g., TFT, conductor, or micro-IC components) positioned along the first side 203 of substrate structure 202, and a plurality of fins 210 positioned along the second side 205 of substrate structure 202, similar to FIG. 2A. The plurality of fins 210 form a plurality of windows 208 between adjacent fins 210. In addition, heat sources 206 are laterally in line with windows 208.

Further, LED device 272 includes a plurality of LEDs 204 positioned along a planarizing layer 222 (or, in some examples, any other intermediate layer) adjacent the first side of substrate structure 202, where each of the plurality of LEDs 204 are laterally offset from the heat sources 206. Moreover, each LED 204 is positioned laterally aligned with a fin 210 of substrate structure 202. The planarizing layer 222 can be a single layer made of a single material or multiple materials and that separate the LEDs 204 from the substrate structure 202.

Because heat from heat sources 206 will tend to follow a path of least resistance, at least some of the heat emitted by each heat source 206 will be directed through substrate structure 202 to the heat source's corresponding window 208. Thus, LED device 272 directs heat from the first side 203 of substrate structure 202 to the second side 205 of the substrate structure 202. A cooling mechanism, such as traditional heat sinking approaches using air flow, metal constructions, or other thermal conductors, may be provided within windows 208 to dissipate the heat, such as by directing the heat out to the environment.

FIG. 2C illustrates an LED device 274 that includes a plurality of heat sources 206 (e.g., TFT, conductor, or micro-IC components) positioned along the first side 203 of substrate structure 202, and a plurality of fins 210 positioned along the second side 205 of substrate structure 202, similar to FIG. 2A. The plurality of fins 210 form a plurality of windows 208 between adjacent fins 210. As in FIG. 2B, heat sources 206 are laterally in line with the windows 208.

In this example, however, LED device 274 includes a plurality of LEDs 204 positioned above the heat sources 206. As illustrated, an LED 204 sits atop of each heat source 206. The LEDs 204 may also be vertically separated from the heat sources 206 by one or more intermediate layers (e.g., a planarizing layer 222) but still be laterally aligned above the heat sources 206. Moreover, each LED 204 and heat source 206 pair is positioned laterally aligned with a window 208 of substrate structure 202.

Here again, because heat from heat sources 206 will follow a path of least resistance, at least some of the heat emitted by each heat source 206 will be directed through substrate structure 202 to the heat source's corresponding window 208. Thus, LED device 274 directs heat from the first side 203 of substrate structure 202 to the second side 205 of the substrate structure 202. A cooling mechanism, such as a gas, metal, or other thermal conductor, may be provided within windows 208 to dissipate the heat, such as by directing the heat out to the environment.

FIG. 2D illustrates an LED device 276 that includes a plurality of heat sources 206 (e.g., TFT, conductor, or micro-IC components) positioned along the first side 203 of substrate structure 202, and a plurality of fins 210 positioned along the second side 205 of substrate structure 202, similar to FIG. 2A. The plurality of fins 210 form a plurality of windows 208 between adjacent fins 210. As in FIG. 2B, heat sources 206 are laterally in line with the windows 208.

In this example, however, LED device 276 includes a plurality of LEDs 244, which may be monochrome (e.g., single light) LEDs (e.g., micro-LEDs emitting blue light), on a planarizing layer 222. Moreover, each of the plurality of LEDs 244 are laterally aligned with a fin 210, and laterally offset from the heat sources 206.

LED device 276 also includes a plurality of color conversion components 242 which may be part of a color conversion layer 213. The color conversion components 242 may receive blue light emitted from an LED 244, and convert at least part of the received blue light to red and/or green light. In this example, each color conversion component 242 is laterally aligned with a fin 210, as well as with an LED 244.

Similar to FIG. 2C, because heat from heat sources 206 will follow a path of least resistance, at least some of the heat emitted by each heat source 206 will be directed through substrate structure 202 to the heat source's corresponding window 208. Thus, LED device 276 directs heat from the first side 203 of substrate structure 202 to the second side 205 of the substrate structure 202. A cooling mechanism, such as a gas, metal, or other thermal conductor, may be provided within windows 208 to dissipate the heat, such as by directing the heat out to the environment.

FIG. 2E illustrates an LED device 278 that includes a plurality of fins 208 positioned along the first side 203 of substrate structure 202. The plurality of fins 210 form a plurality of windows 208 between adjacent fins 210. An adhesive 234, such as an acrylic, epoxy, urethane acrylate, UV-curable adhesive, or pressure sensitive adhesive adheres a plurality of heat sources 206 (e.g., TFTs, conductors, or micro-IC components) and a plurality of LEDs 204 along a second side 205 of substrate structure 202. Moreover, a glass sheet 212 is positioned over the second side 205 of substrate structure 202 through which LEDs 204 emit light. The glass sheet 212 can be mechanically coupled directly or through intermediate coatings to the heat sources 206 and LEDs 204.

In this example, the plurality of LEDs 204 are laterally aligned with the plurality of fins 210, whereas the plurality of heating sources 206 are laterally aligned with the plurality of windows 208. In this example as well, because heat from heat sources 206 will follow a path of least resistance, at least some of the heat emitted by each heat source 206 will be directed through substrate structure 202 to the heat source's corresponding window 208. A cooling mechanism, such as a gas, metal, or other thermal conductor, may be provided within windows 208 to dissipate the heat, such as by directing the heat out to the environment.

As illustrated in FIGS. 2A, 2B, 2C, 2D, and 2E, substrate structure 202 includes areas of thin windows 208 that may be period-aligned (e.g., pitch-aligned) to the heat sources 206, thereby creating a short path for heat to be conducted to the cooling environment (e.g., along a surface of the substrate structure 202).

One of skill in the art will readily understand that FIGS. 1 and 2A-E may represent a cross-section of a planar array of devices and/or LED devices that may be used, for example, a in mobile device, laptop, tablet, computer monitor, and/or television display.

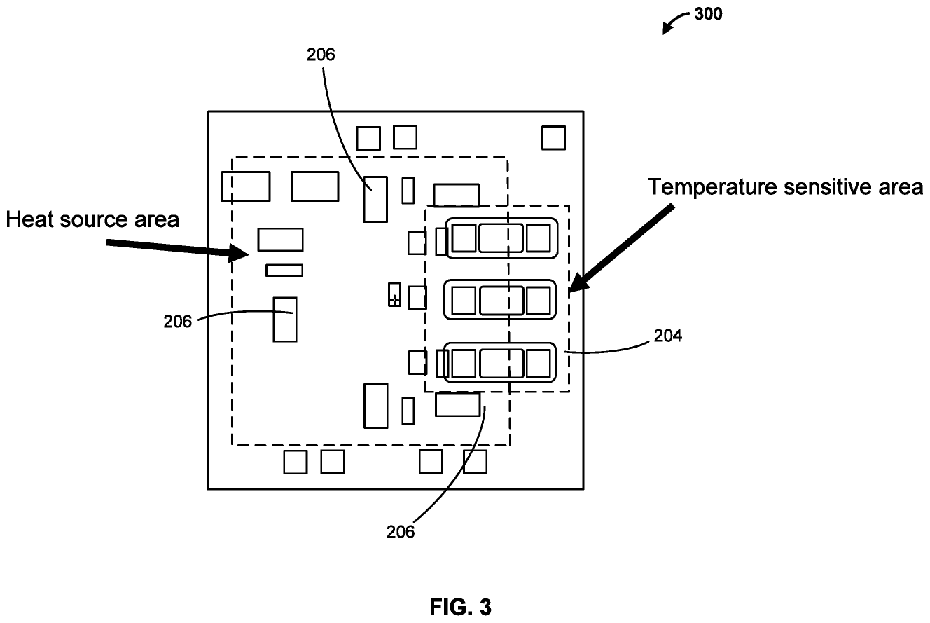

Advantageously, the embodiments may allow heat to be extracted from the substrate structure 202 before the heat can laterally spread to nearby temperature sensitive components. As shown in FIG. 3, major heat sources 206 (e.g., semiconductor components) can occupy a majority of a pixel area in a micro-LED display 300. Since the LED 204 temperature sensitive zone occupies less area than a TFT heat-generation area, the substrates ability to absorb the heat without affecting LED's 204 performance is limited. Although LED 204 is mentioned, alternative elements can include micro-LEDs, mini-LEDs, color conversion elements, or combinations of these or other components. Similarly, although a TFT area is mentioned, the area may include other heat-generation materials such as ICs, micro-ICs, and conductors.

To cure these and other deficiencies, the embodiments channel heat (e.g., via isolated heat flow channels) from the heat sources 206 in a way that reduces thermal increase of the LEDs 206. As a result, a higher thermal gradient may be created through the thickness of the substrate structure 202 in isolated areas (e.g., via the plurality of fins 210).

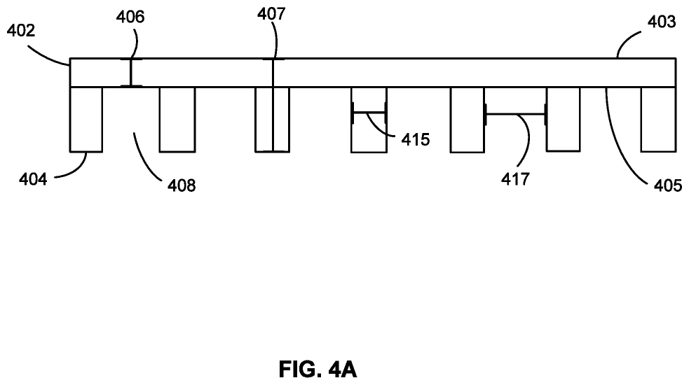

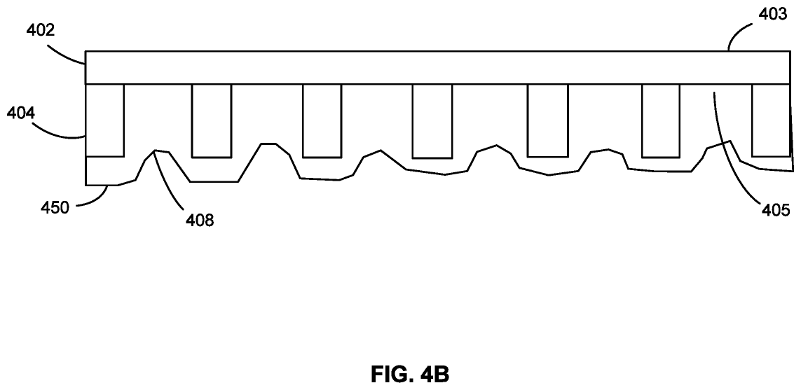

With reference to FIG. 4A, a first surface 403 of substrate structure 402 provides an optimized area for device fabrication. A second surface 405 of substrate structure 402, though, incudes a plurality of fins 404. The plurality of fins 404 may be manufactured out of the same or different materials as the remainder of substrate structure 402.

Thin window areas 406 of substrate structure 402 are designed to transfer heat from heat sources, such as heat sources 206, and thus windows 408 may be aligned to the heat sources. To promote primarily heat transfer through the substrate structure 402 instead of laterally across substrate structure 402, the substrate structure 402 is manufactured to have thin window areas 406 with a thickness less than or equal to a threshold percentage of a period of LEDs positioned along first surface 403 (e.g., pixel pitch). For example, a distance from the first side to the second side of the substrate (e.g., distance of thin window area 406) may be less than 30% of the LED period. Thin window areas 406 may be formed by removing substrate material from substrate structure 402 to carve out the plurality of windows 408 (e.g., under where heat sources may be placed along first surface 403). As other examples, substrate structure 102 may be manufactured to have a window thickness 142 that is less than or equal to 10% of the LED period, less than or equal to 50% of the LED period, less than or equal to 70% of the LED period, or less than or equal to 90% of the LED period.

Thick substrate areas 407, which include the plurality of fins 404, are thicker and may add overall mechanical support. In some examples, substrate structure 402 may be manufactured to have thin window areas 406 with a thickness that is less than a threshold percentage of the substrate thickness at thick substrate areas 407. Moreover, substrate structure 402 may be manufactured to have a fin width 415 of each of the plurality of fins 404 that is proportional to a distance 417 between adjacent fins 404. For example, distance 417 may be greater than fin width 415 by a threshold amount (e.g., such as 50% greater, 100% greater, 200% greater, or 300% greater).

In some examples, a substrate material for substrate structure 402 can be chosen based on the application and device fabrication requirements. For example, the substrate material may be a dielectric material such as a glass, ceramic, glass ceramic, or polymer material. The substrate structure 402 can also be manufactured from a combination of materials. For example, the thicker support portion of the substrate (e.g., thick substrate areas 407) can be a glass, and the thinner window portion (e.g., thin window areas 406) can be a ceramic. One reason to combine materials is to utilize material such as ceramic that is optimized to be thinner and have higher thermal conductivity and diffusivity for the window regions (e.g., thin window areas 406). Glass substrates optimized for large area panel processing can then be used for the support areas (e.g., thick substrate areas 407). Examples of thin ceramic materials include alumina and zirconia substrates less than 100 um thick.

The thin window portions 406 can be a single material, layered, or a composite. Also, the fins 404 can be a single material, layered, or a composite. The thin window portions 406 may vary in lateral dimension across the substrate structure 402. Likewise, the fins 404 may vary on lateral dimension across the substrate structure 402. Even though they are depicted as rectangular elements, the fins 404 and thin window portions 406 may have non-vertical, non-horizontal, curved, sloped, and otherwise non-linear surfaces. Additionally, the fins 404 and thin window portions 406 may be linear arrays, non-linear arrays, 2D arrays, or other patterns across the substrate surface. Although the thickness variation is depicted only existing on the second surface, the thickness variation can also exist on the first surface 403 or a combination of first and second surfaces 403, 405 of the substrate structure 402. In some examples, the thin window areas 406, thick substrate areas 407, and fin widths 415 may vary across the substrate structure 402.

If thin window areas 406 and thick substrate areas 407 of the substrate structure 402 are manufactured from different materials, they can be assembled by lamination, coating, deposition, or bonding processes. If they are two differing types of glass materials, they can be formed in a laminate fusion process. The backside surface (e.g., second surface 405) features can be formed through etch, ablation, molding or other processes as known in the art. For example, the material of thick substrate areas 407 can be combined with material of the thin window areas 406 as a uniform sheet and then have material removed to from fins 404.

The plurality of windows 408 also allow for the cooling of substrate structure 402. For example, heat may be transferred from the substrate structure 402 to the environment using air flow (e.g., a fan blowing air through the plurality of windows 408), a thermal conductor or heat sink thermally coupled to a heat conduction material dispersed between the plurality of fins 404, or by thermal radiation to the surroundings. A heat conduction material facilitates the transfer of heat away from substrate structure 402 and, for example, to the environment. These additional elements can be integrated onto the second surface 405 of the substrate structure 402 and either coating or filling in the plurality of windows 408. One advantage is the increased surface area on the second surface 405 that can be used for heat transfer either directly to the environment or through an intermediate heat conduction layer. As examples, the heat conduction material can be a metal or an anisotropic heat conduction material that conducts heat away from the second surface 405. An anisotropic heat conduction material may be a conformal or planarizing coating, or an integrated element, for example. The heat conduction material may be electrically compatible with corresponding electrical circuits and (e.g., first surface 403 and second surface 405) interconnects. For example, the heat conduction material may support electronic or optical elements such as conductors, ICs, micro-ICs, LEDs, color conversion materials, emitters, lens structures, optical scattering structures.

As an example, FIG. 4B illustrates the same substrate structure 402 of FIG. 4A, but with a heat conduction material 450 dispersed between the plurality of fins 404. Heat conduction material 450 may be isotropic or anisotropic, for example. Heat conduction material 450 facilitates the transfer of heat from substrate structure 402 to the environment from the substrate structure's 402 backside (e.g., second surface 405). The plurality of fins 408, at least because they add surface area that is in contact with the heat conduction material 450, improve heat dissipation from substrate material 402.

In some examples, an insulating layer, electrical circuits, and wrap-around electrode interconnects, through-substrate via electrical interconnects, may be added. In some examples, cooling may be further improved by applying a high emissivity coating to the heat conduction material 450, or directly to the substrate structure's backside (e.g., second surface 405) (e.g., such as when additional heat conduction provided by the heat conduction material 450 is not required).

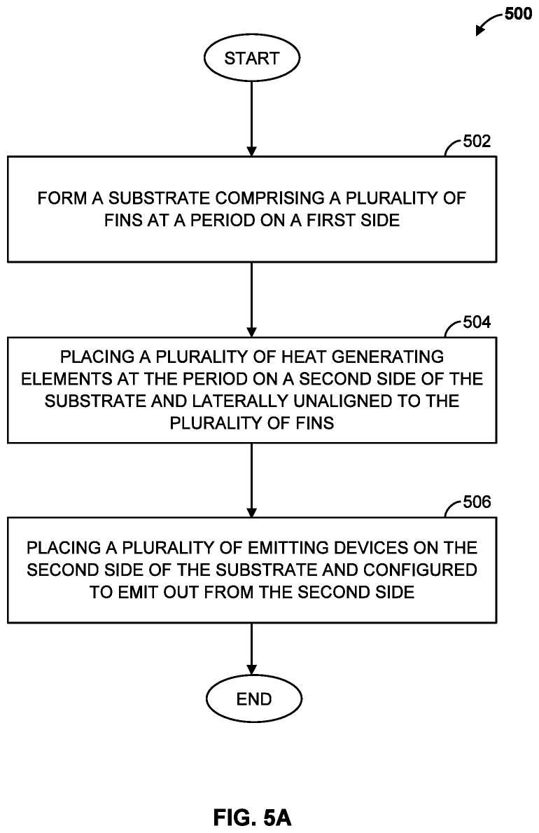

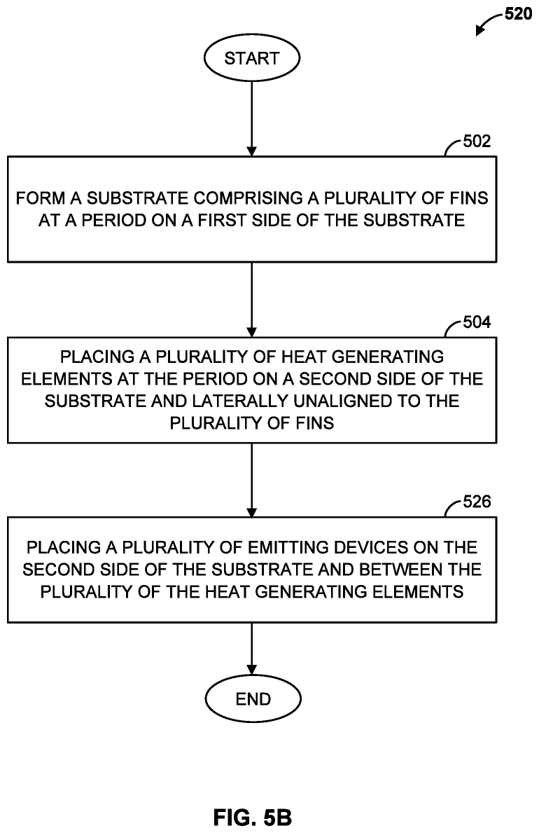

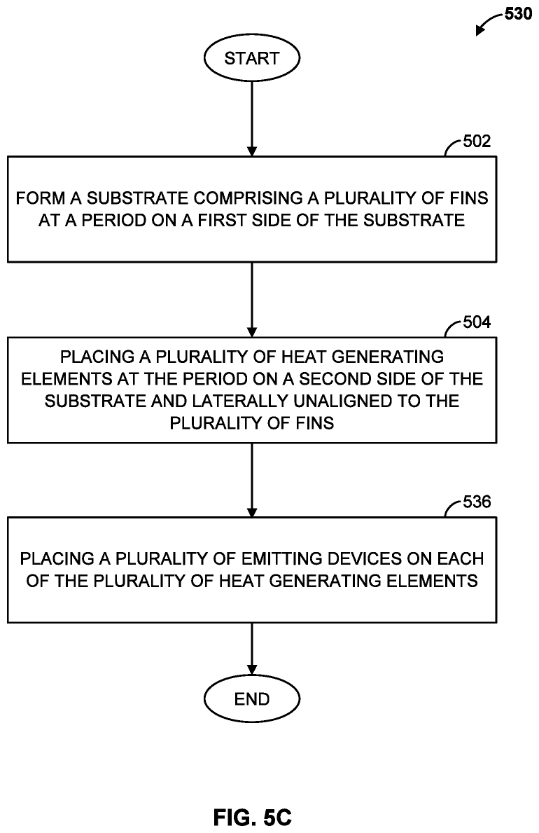

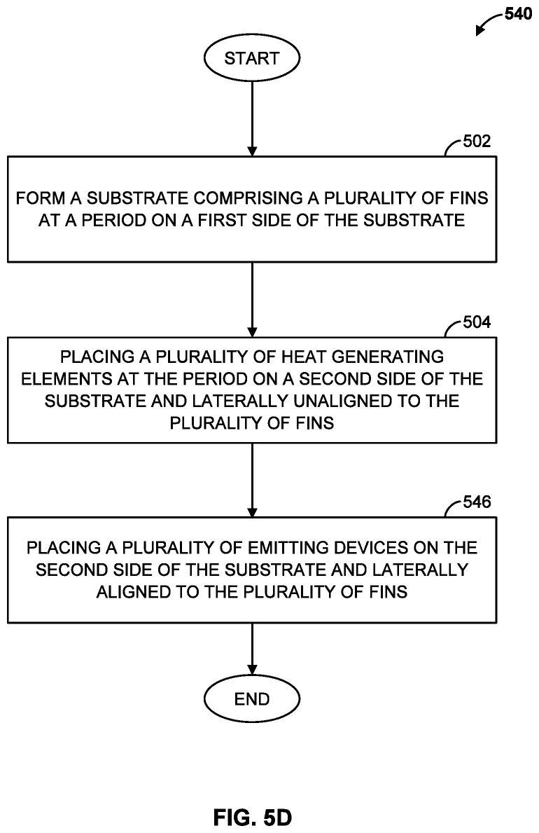

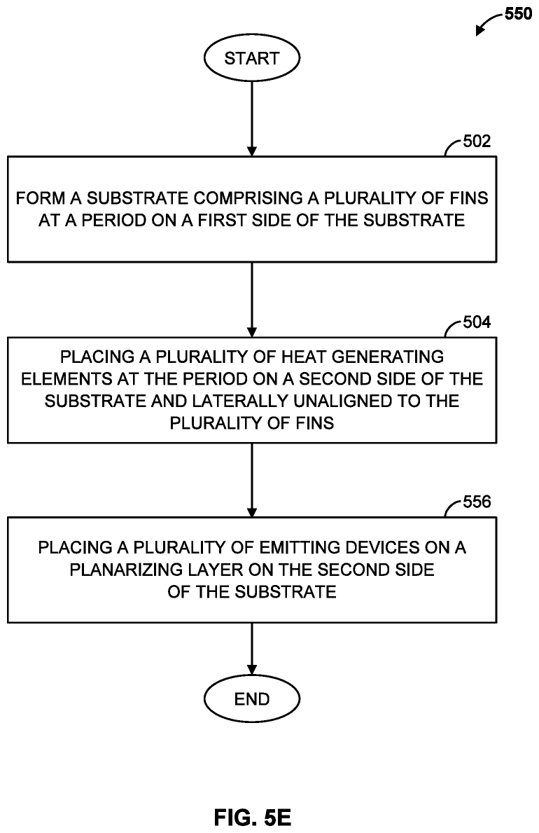

FIGS. 5A, 5B, 5C, 5D, and 5E illustrate an exemplary methods to forming devices with a substrate structure, heat generating elements (e.g., heat sources 206), and LEDs (e.g., LEDs 204, 244). Referring to FIG. 5A, method 500 includes, at step 502, forming a substrate comprising a plurality of fins at a period on a first side. For example, the substrate, including the fins, may be formed of glass, ceramic, glass ceramic, or polymer material. At step 504, a plurality of heat generating elements, such as heat sources 206, are placed at the same period on a second side of the substrate, and laterally unaligned to the plurality of fins. For example, FIG. 2A illustrates a plurality of heating elements 206 placed along one side of substrate structure 202 at a same pitch as a plurality of fins 210 positioned along another side of the substrate structure 202. The heat sources 206 are laterally unaligned to the plurality of fins 210.

At step 506, a plurality of emitting devices, such as LEDs 204, 244, are placed on the second side of the substrate, configured to emit (e.g., light) out (e.g., away) from the second side. For example, FIG. 2A illustrates a plurality of LEDs 206 placed on another side of substrate structure 202 than the side with the plurality of fins 210. The method then ends.

FIG. 5B illustrates a method 520 that also includes, at step 502, forming a substrate comprising a plurality of fins at a period on a first side, and at step 504, placing a plurality of heat generating elements at the same period on a second side of the substrate, and laterally unaligned to the plurality of fins.

Proceeding to step 526, a plurality of emitting devices are placed on the second side of the substrate and between the plurality of heat generating elements. For example, FIG. 2B illustrates a plurality of LEDS 204, each LED 204 positioned between heat sources 206. The method then ends.

FIG. 5C illustrates a method 530 that also includes, at step 502, forming a substrate comprising a plurality of fins at a period on a first side, and at step 504, placing a plurality of heat generating elements at the same period on a second side of the substrate, and laterally unaligned to the plurality of fins.

At step 536, a plurality of emitting devices are placed on each of the plurality of heat conducting elements. For example, FIG. 2C illustrates an LED 204 positioned on top of each of a plurality of heat sources 206. The method then ends.

FIG. 5D illustrates a method 540 that also includes, at step 502, forming a substrate comprising a plurality of fins at a period on a first side, and at step 504, placing a plurality of heat generating elements at the same period on a second side of the substrate, and laterally unaligned to the plurality of fins.

At step 546, a plurality of emitting devices are placed on the second side of the substrate and laterally aligned to the plurality of fins. For example, FIG. 2A illustrates a plurality of LEDs 206 placed on another side of substrate structure 202 than the side with the plurality of fins 210, where the plurality of LEDs 206 are laterally aligned to the plurality of fins 210. The method then ends.

FIG. 5E illustrates a method 550 that also includes, at step 502, forming a substrate comprising a plurality of fins at a period on a first side, and at step 504, placing a plurality of heat generating elements at the same period on a second side of the substrate, and laterally unaligned to the plurality of fins.

At step 556, a plurality of emitting devices are placed on a planarizing layer on the second side of the substrate. For example, FIG. 2B illustrates a plurality of LEDS 204, each LED 204 placed on a planarizing layer 222 on a side of substrate structure 202 opposite a side with the plurality of fins 210. The method then ends.

In some examples, a device comprises a substrate with a first side and a second side opposite the first side. The device also comprises a plurality of heat sources positioned on the first side of the substrate at a period, and a plurality of fins positioned along the second side of the substrate at the period. In some examples, the period is in the range of 25 um to 250 um. The plurality of heat sources may be laterally offset from the plurality of fins.

In some examples, the device comprises a plurality of light-emitting diodes (LEDs) at least partially laterally in line with the plurality of fins. In some examples, the plurality of heat sources are laterally offset from each of adjacent fins of the plurality of fins. In some examples, the plurality of LEDs laterally offset from the plurality of fins. In some examples, each of the plurality of LEDs are positioned on one of the plurality of heat sources.

In some examples, the plurality of fins define a plurality of windows along the second side. In some examples, plurality of windows are laterally in line with the plurality of heat sources. In some examples, a distance from the first side to the second side of the substrate is less than 30% of the period.

In some examples, the substrate comprises a plurality of first portions and second portions, the first portions longer than the second portions, and the second portions defined, at least in part, by a top side of the plurality of windows. In some examples, a length of each of the first portions are at least twice as long as a length of each of the second portions.

In some examples, a heat conduction material is dispersed within the plurality of windows, wherein the heat conduction material is configured to dissipate heat from the substrate.

In some embodiments, a light-emitting diode (LED) display comprises a glass sheet and a plurality of LED devices positioned on a side of (e.g., under) the glass sheet. Further, each of the plurality of LED devices comprises a substrate with a first side and a second side opposite the first side, and a plurality of heat sources positioned on the first side of the substrate at a period. In some examples, the period is in the range of 25 um to 250 um. Each of the plurality of LED devices also comprise a plurality of fins positioned along the second side of the substrate at the period. The plurality of heat sources may be laterally offset from the plurality of fins.

In some examples, each of the plurality of LED devices comprise a plurality of light-emitting diodes (LEDs) at least partially laterally in line with the plurality of fins. In some examples, the plurality of heat sources are laterally offset from each of adjacent fins of the plurality of fins. In some examples, the plurality of LEDs laterally offset from the plurality of fins. In some examples, each of the plurality of LEDs are positioned on one of the plurality of heat sources.

In some examples, the plurality of fins define a plurality of windows along the second side. In some examples, plurality of windows are laterally in line with the plurality of heat sources. In some examples, a distance from the first side to the second side of the substrate is less than 30% of the period.

In some examples, each of the substrates comprise a plurality of first portions and second portions, the first portions longer than the second portions, and the second portions defined, at least in part, by a top side of the plurality of windows. In some examples, a length of each of the first portions are at least twice as long as a length of each of the second portions.

In some examples, a heat conduction material is dispersed within the plurality of windows, wherein the heat conduction material is configured to dissipate heat from the substrate.

In some embodiments, a method comprises forming a substrate comprising a first side and a second side opposite the first side, wherein the first side comprises a plurality of fins at a period, and placing a plurality of heat generating elements at the period on the second side of the substrate and laterally offset from the plurality of fins.

In some examples, the method comprises placing a plurality of LEDs on the second side of the substrate and laterally offset from the plurality of fins. In some examples, the method comprises placing the plurality of LEDs at least partially laterally in line with the plurality of fins.

In some examples, the method comprises placing the plurality of heat sources laterally offset from each of adjacent fins of the plurality of fins. In some examples, the method comprises placing each of the plurality of LEDs on one of the plurality of heat sources.

In some examples, the plurality of fins define a plurality of windows along the second side, wherein the method comprises dispersing a heat conduction material within the plurality of windows, wherein the heat conduction material is configured to dissipate heat from the substrate.

In some embodiments, a non-transitory computer readable medium stores instructions that, when executed by one or more processors, cause the one or more processors to perform a method that includes forming a substrate comprising a first side and a second side opposite the first side, wherein the first side comprises a plurality of fins at a period, and placing a plurality of heat generating elements at the period on the second side of the substrate and laterally offset from the plurality of fins.

In some examples, the method comprises placing a plurality of LEDs on the second side of the substrate and laterally offset from the plurality of fins. In some examples, the method comprises placing the plurality of LEDs at least partially laterally in line with the plurality of fins.

In some examples, the method comprises placing the plurality of heat sources laterally offset from each of adjacent fins of the plurality of fins. In some examples, the method comprises placing each of the plurality of LEDs on one of the plurality of heat sources.

In some examples, the plurality of fins define a plurality of windows along the second side, wherein the method comprises dispersing a heat conduction material within the plurality of windows, wherein the heat conduction material is configured to dissipate heat from the substrate.

Although the methods described above are with reference to the illustrated flowcharts, it will be appreciated that many other ways of performing the acts associated with the methods can be used. For example, the order of some operations may be changed, and some of the operations described may be optional.

In addition, the methods and system described herein can be at least partially embodied in the form of computer-implemented processes and apparatus for practicing those processes. The disclosed methods may also be at least partially embodied in the form of tangible, non-transitory machine-readable storage media encoded with computer program code. For example, the steps of the methods can be embodied in hardware, in executable instructions executed by a processor (e.g., software), or a combination of the two. The media may include, for example, RAMs, ROMs, CD-ROMs, DVD-ROMs, BD-ROMs, hard disk drives, flash memories, or any other non-transitory machine-readable storage medium. When the computer program code is loaded into and executed by a computer, the computer becomes an apparatus for practicing the method. The methods may also be at least partially embodied in the form of a computer into which computer program code is loaded or executed, such that, the computer becomes a special purpose computer for practicing the methods. When implemented on a general-purpose processor, the computer program code segments configure the processor to create specific logic circuits. The methods may alternatively be at least partially embodied in application specific integrated circuits for performing the methods.

The foregoing is provided for purposes of illustrating, explaining, and describing embodiments of this disclosure. Modifications and adaptations to these embodiments will be apparent to those skilled in the art and may be made without departing from the scope or spirit of this disclosure.

What is claimed is:

1. A device comprising:
a substrate with a first side and a second side opposite the first side;
a plurality of heat sources positioned on the first side of the substrate at a period; and
a plurality of fins positioned along the second side at the period, wherein the plurality of heat sources are laterally offset from the plurality of fins.

2. The device of claim 1, further comprising a plurality of light-emitting diodes (LEDs) at least partially laterally in line with the plurality of fins.

3. The device of claim 2, wherein each of the plurality of heat sources are laterally offset from each of adjacent fins of the plurality of fins.

4. The device of claim 1, further comprising a plurality of LEDs laterally offset from the plurality of fins.

5. The device of claim 4, wherein each of the plurality of LEDs are positioned on one of the plurality of heat sources.

6. The device of claim 1, wherein the plurality of fins define a plurality of windows along the second side.

7. The device of claim 6, wherein the plurality of windows are laterally aligned with the plurality of heat sources.

8. The device of claim 6, wherein a closest distance between the first side and the second side of the substrate is less than 30% of the period.

9. The device of claim 6, wherein the substrate comprises a plurality of first portions and second portions, the first portions longer than the second portions between the first side and the second side, and the second portions defined, at least in part, by a top side of the plurality of windows.

10. The device of claim 9, wherein a length of each of the first portions are at least twice as long as a length of each of the second portions.

11. The device of claim 6 further comprising a heat conduction material dispersed within the plurality of windows, wherein the heat conduction material is configured to dissipate heat from the substrate.

12. The device of claim 1, wherein the plurality of heat sources are positioned proximate the first side of the substrate at the period.

13. The device of claim 1, wherein the period is in the range of 25 um to 250 um.

14. A light-emitting diode (LED) display comprising:
a glass sheet; and
a plurality of LED devices positioned on a side of the glass sheet, wherein each of the plurality of LED devices comprises:
a substrate with a first side and a second side opposite the first side;
a plurality of heat sources positioned on the first side of the substrate at a period; and
a plurality of fins positioned along the second side at the period, wherein the plurality of heat sources are laterally offset from the plurality of fins.

15. The LED display of claim 14, wherein each of the plurality of LED devices further comprise a plurality of light-emitting diodes (LEDs) at least partially laterally aligned with the plurality of fins.

16. The LED display of claim 15, each of the plurality of heat sources are laterally offset from each of adjacent fins of the plurality of fins.

17. The LED display of claim 14, wherein each of the plurality of LED devices further comprise a plurality of LEDs laterally offset from the plurality of fins.

18. The LED display of claim 14, wherein each of the plurality of fins define a plurality of windows along the second side of the substrate.

19. The LED display of claim 18, wherein each of the substrates further comprise a plurality of first portions and second portions, the first portions longer than the second portions between the first side and the second side, and the second portions defined, at least in part, by a top side of the plurality of windows.

20. The LED display of claim 18, wherein each of the plurality of LED devices further comprise a heat conduction material dispersed within the plurality of windows, wherein the heat conduction material is configured to dissipate heat from the substrate.

21. The LED display of claim 14, wherein the period is in the range of 25 um to 250 um.

22. A method comprising:
forming a substrate comprising a first side and a second side opposite the first side, wherein the first side comprises a plurality of fins at a period; and
placing a plurality of heat generating elements at the period along the second side of the substrate and laterally offset from the plurality of fins.

23. The method of claim 22, further comprising placing a plurality of LEDs on the second side of the substrate and laterally offset from the plurality of fins.

24. The method of claim 22, wherein comprises placing the plurality of fins at the period along the first side of the substrate.
